(19) United States
(12) Patent Application Publication
(10) Pub. No.: US 2026/0327068 A1
(43) Pub. Date: Oct. 22, 2026

(54) PRODUCTION METHOD WITH TEMPORARY PROTECTION OF MICROSTRUCTURES

(71) Applicant: Robert Bosch GmbH, Stuttgart (DE)

(72) Inventor: Michael Knauss, Pfullingen (DE)

(21) Appl. No.: 19/119,431

(22) PCT Filed: Nov. 23, 2023
(86) PCT No.: PCT/EP2023/082808

§ 371 Date: Apr. 9, 2025

(30) Foreign Application Priority Data
Jan. 3, 2023 (DE) 10 2023 200 049.0

(51) Int. Cl. B81C 1/00

(52) U.S. Cl. CPC B81C 1/00793

(57) ABSTRACT

A method for producing semiconductor components having microstructures. A base wafer having a plurality of microstructures is provided; a cap wafer is arranged on the base wafer and is integrally bonded to the base wafer in order to form a wafer assembly; the microstructures are closed off, at least on one side, with respect to an environment by the arranged cap wafer; at least one manufacturing step and/or processing step and/or separating step is performed; and at least a part of the cap wafer or some separated portions of the cap wafer is or are removed from the base wafer or from separated portions of the base wafer.

### FIELD

The present invention relates to a method for producing semiconductor components having microstructures, in which a base wafer having a plurality of microstructures is provided.

### BACKGROUND INFORMATION

In the manufacture of open MEMS structures or microstructures in semiconductor components, the protection of these delicate and sensitive microstructures is a challenge. In particular, such microstructures must be protected from contamination, for example by particles, liquid chemical substances, and required process substances, and from mechanical damage. When contaminated by particles, the microstructures can be blocked by the particles and are subsequently no longer functional. Contamination with chemical substances can result in the microstructures sticking together, as a result of which the stuck microstructures likewise no longer have the desired functionality.

To protect the microstructures from contamination with particles, methods that are implemented in clean rooms are conventional. However, protecting the microstructures from chemical substances that must be used during production is problematic. In addition, open microstructures are potentially vulnerable to damage and contamination when the wafers are processed further during the singulation of the MEMS chips and the subsequent assembly and connection technology. In particular, when the wafer is singulated into MEMS chips having open microstructures, the normal sawing process with diamond disk and water for cleaning is excluded, which limits the choice of technologies for producing the wafers.

### SUMMARY

An object of the present invention is to create a wafer-based production method for microstructures that are open to an environment, which method protects the microstructures from harmful effects at least during the production method.

This object may be achieved by means of certain features of the present invention. Advantageous embodiments of the present invention are disclosed herein.

According to one aspect of the present invention, a method for producing semiconductor components having microstructures is provided. According to an example embodiment of the present invention, in one step of the method, a base wafer having a plurality of microstructures is provided. The microstructures can, for example, be designed as MEMS structures, which are required for the operation of micromirrors, u-phones, MEMS speakers, pressure and environmental sensors and the like. Such arrangements with microstructures require access to the environment and therefore cannot be hermetically encapsulated as a semiconductor component or chip. The microstructures are therefore potentially at risk of damage and contamination throughout the process chain (wafer process, singulation, AVT, etc.).

In a further step of the method of the present invention, a cap wafer is arranged on the base wafer and is integrally bonded to the base wafer to form a wafer assembly. In this wafer assembly, the microstructures are closed off, at least on one side, with respect to an environment by the arranged cap wafer. This step allows protection of the microstructures throughout the production process.

After the application of the at least one cap wafer, which can be applied to one side or both sides of the base wafer, at least one manufacturing step and/or processing step and/or separating step is performed. Thus, the choice of available manufacturing technologies is not limited, as a result of which no compromises need to be made regarding the manufacturing technology of the semiconductor components.

According to an example embodiment of the present invention, in a further step, which can optionally be designed as a final step, at least a part of the cap wafer or some separated portions of the cap wafer is or are removed from the base wafer or from separated portions of the base wafer.

The at least one previously applied cap wafer can thus be moved before a separating step or after a separating step. For example, a choice of technique for singulating the semiconductor components from the wafer assembly can decide whether the cap wafer or portions of the cap wafer are removed after or before the separating step.

According to an example embodiment of the present inventio, the at least one cap wafer is removed before singulation. After a separating step or the singulation of the wafer assembly, the interconnected cap wafers and base wafers having microstructures are present in a plurality of portions, which are individually detached from one another after singulation.

The method allows the microstructures to be protected throughout the production process. For example, the protection can be realized by hermetic bonding of the at least one cap wafer made of silicon or glass.

The microstructures are protected by the cap wafer, and the system or wafer assembly can be further produced or processed without limitation of the manufacturing steps throughout the production process.

Processes on the underside of the base wafer, which could lead to damage to the microstructures in an open system, are also made possible without limitations. The at least one cap wafer acts as structural reinforcement.

For example, thanks to the method, the wafer assembly can also be singulated by conventional sawing. Such singulation would not be possible with open microstructures due to the use of water (for cooling and cleaning) and the dust (particles) generated during sawing.

After the overall system is finished or the production process is completed, the microstructures in the wafer assembly as a whole or the singulated MEMS chips in the form of semiconductor components can be detached from the cap wafer. The detachment can be carried out, for example, by horizontal slicing.

According to one aspect of the present invention, a sensor assembly is provided. The sensor assembly can, for example, be in the form of a micro-electro-mechanical system (MEMS) and has at least one portion of the base wafer that has at least one microstructure.

In one exemplary embodiment of the present invention, the cap wafer is bonded to the base wafer by direct wafer bonding or anodic bonding, by seal glass bonding, or by eutectic bonding. By this measure, the at least one cap wafer can be used to hermetically seal the microstructures on the base wafer on the basis of different bonding methods.

According to a further embodiment of the present invention, at least a part of the cap wafer is detached from the base wafer by horizontal stealth dicing of a bond layer or the cap wafer. Thus, the cap wafer or a part or portion of the cap wafer can be removed from the base wafer, for example by so-called Kabra slicing. Such a detachment method allows rapid and precise opening of the previously sealed microstructures with a minimal risk of contamination, for example by particles.

According to a further exemplary embodiment of the present invention, at least some separated portions of the cap wafer are detached from separated portions of the base wafer by horizontal stealth dicing of a bond layer or of separated portions of the cap wafer.

Depending on the design, the cap wafer or portion of the cap wafer can be completely detached from the base wafer along the connecting layer. In an alternative or additional embodiment, the cap wafer or portions of the cap wafer can also be detached at a vertical position deviating from the connecting layer. In this case, fragments or remnants of the cap wafer may remain on the base wafer or portions of the base wafer.

According to a further embodiment of the present invention, a cap wafer structured in the direction of the base wafer is arranged on the base wafer and connected to the base wafer. As an alternative to an unstructured or smooth cap wafer, a structure that is present in the region of the microstructures can be embossed onto the cap wafer. This allows, for example, microstructures protruding from the base wafer to be protected by the cap wafer. Alternatively, the microstructures can be protected with a cavity or a plurality of cavities introduced into the cap wafer. Advantageously, a cavity can be provided in the cap wafer for each microstructure and located exactly above the microstructure to be protected.

According to a further exemplary embodiment of the present invention, the microstructures are exposed by at least partially removing the cap wafer after the at least one manufacturing step and/or processing step and/or separating step. For example, using a suitable laser, a so-called stealth layer can be created in the material of the cap wafer above the wafer bonding point as the connecting layer. The cap wafer can then be removed along this (predetermined) breaking point.

This works technically in a particularly simple manner on the previously singulated MEMS chip. Here, the portion of the cap wafer can be simply lifted via a conventional pick & place process using an appropriate pick tool.

According to a further embodiment of the present invention, for at least partial removal of the cap wafer, at least one horizontally running stealth layer is introduced into the cap wafer and a detachment is carried out along the horizontally running stealth layer.

If the detachment of the cap wafer or a part of the cap wafer takes place after the wafer assembly has been singulated, at least one horizontally running stealth layer is introduced into the singulated or separated portions of the cap wafer and a detachment is carried out along the horizontally running stealth layer. This means that the microstructures can only be released and put to their intended use at the end of the entire process chain.

According to a further exemplary embodiment of the present invention, a plurality of semiconductor components with exposed microstructures are produced by at least partially detaching separated portions of the cap wafer. In an alternative embodiment, a plurality of semiconductor components with exposed microstructures are produced by at least partial detachment of the cap wafer and then separation. By means of these measures, protection can be implemented before or after singulation of the respective semiconductor components. This allows the production method to be carried out efficiently without considering possible contamination of the microstructures.

Preferred exemplary embodiments of the present invention are explained in more detail below with reference to highly simplified schematic representations.

### BRIEF DESCRIPTION OF THE DRAWINGS

FIG. 1 is a sectional view of a wafer assembly according to the present invention in an exemplary embodiment to illustrate a method according to an example embodiment of the present invention.

FIG. 2 is a sectional view of a wafer assembly according to the present invention in a further exemplary embodiment to illustrate a method according to an example embodiment of the present invention.

FIG. 3 is a sectional view of a wafer assembly according to the present invention with an introduced stealth layer to illustrate the method according to an example embodiment of the present invention.

FIG. 4 is a sectional view of a base wafer with a cap wafer partially removed along the stealth layer to illustrate the method according to an example embodiment of the present invention.

FIG. 5 shows sectional views to illustrate a method according to the present invention according to a further exemplary embodiment.

### DETAILED DESCRIPTION OF EXAMPLE EMBODIMENTS

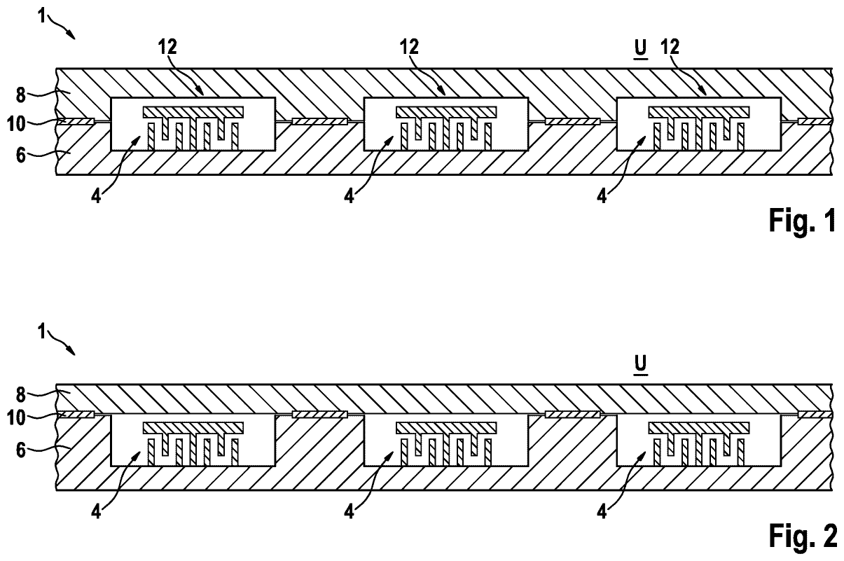

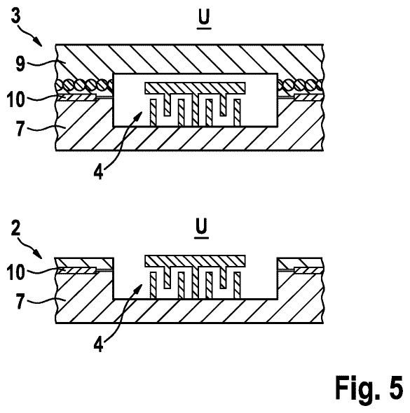

FIG. 1 shows a sectional view of a wafer assembly 1 according to the present invention in an exemplary embodiment to illustrate a method according to the present invention. The method is used to produce semiconductor components 2 having microstructures 4. The separated semiconductor components 2 with microstructures 4 are shown by way of example in FIG. 5.

In one step of the method, a base wafer 6 having a plurality of microstructures 4 is provided. The microstructures 4 are designed by way of example as MEMS structures. In a further step of the method, a cap wafer 8 is arranged on the base wafer 6 and is integrally bonded to the base wafer 6 in order to form the wafer assembly 1, which is shown in FIG. 1 and FIG. 2. In this wafer assembly 1, the microstructures 4 are closed off on one side with respect to an environment U by the arranged cap wafer 8.

In FIG. 1, a cap wafer 8 structured in the direction of the base wafer 6 is arranged on the base wafer 6 and connected to the base wafer 6 by means of a connecting layer 10. By means of the structuring of the cap wafer 8, a plurality of cavities 12 or recesses are made in the cap wafer 8. For each microstructure 4, a cavity 12 is provided in the cap wafer 8 in order to accommodate the microstructure 4 in question.

FIG. 2 shows a further sectional view of a wafer assembly 1 according to the present invention in a further exemplary embodiment to illustrate a method according to the present invention. An alternative wafer assembly 1 is shown in which an unstructured cap wafer 8 is used to hermetically seal or protect the microstructures 4.

This step of the method shown in FIG. 1 and FIG. 2 allows the protection of the microstructures 4 during the entire production process. After the application of the at least one cap wafer 8, which can be applied to one side or both sides of the base wafer 6, at least one manufacturing step and/or processing step and/or separating step is performed, which is not described in more detail for the sake of simplicity.

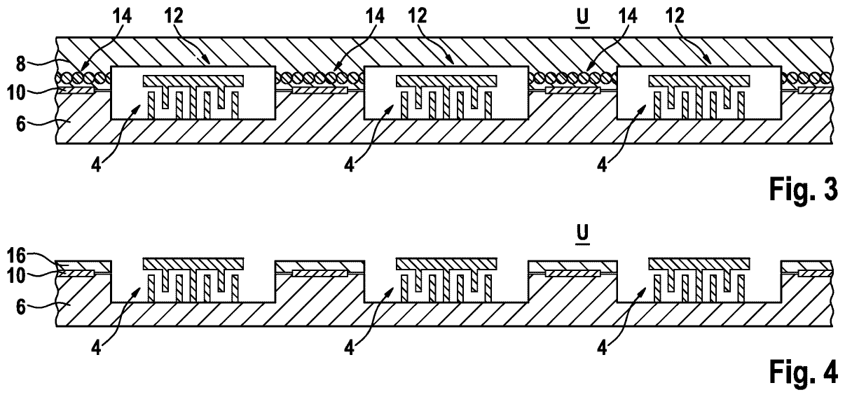

FIG. 3 shows a sectional view of a wafer assembly 1 according to the present invention with an introduced stealth layer 14 to illustrate a further step of the method according to the present invention. Here, a horizontally running stealth layer 14 is introduced into the cap wafer 8 by way of example at a vertical position of the wafer assembly 1 that deviates from the connecting layer 10.

In a subsequent step, the cap wafer 8 is partially detached along the horizontally running stealth layer 14. The result of the detachment is shown in FIG. 4, which illustrates a sectional view of the base wafer 6 with a cap wafer 8 partially removed along the stealth layer 14. FIG. 4 also shows remaining fragments 16 of the cap wafer 8, which are connected to the base wafer 6 by means of the connecting layer 10.

By means of an at least partial removal of the cap wafer 8 after the at least one manufacturing step and/or processing step, the microstructures 4 are exposed. For example, using a suitable laser, a so-called stealth layer 14 can be created in the material of the cap wafer 8 above the wafer bonding point as the connecting layer 10. The cap wafer 8 can then be removed along this (predetermined) breaking point.

Depending on the design of the method, a separating step can then be carried out in order to produce a plurality of semiconductor components 2.

FIGS. 3 and 4 illustrate by way of example the further processing of the wafer assembly 1 shown in FIG. 1 with a structured cap wafer 8.

FIG. 5 shows sectional views to illustrate a method according to the present invention according to a further exemplary embodiment. In one step, the wafer assembly 1 shown in FIG. 1 is separated into portions 3. For example, the wafer assembly 1 can be singulated by conventional sawing.

After the separating step or the singulation of the wafer assembly 1, the interconnected cap wafers 8 and base wafers 6 having microstructures 4 are present in a plurality of portions 7, 9, which are detached from one another after singulation.

Here, at least a part of the separated portion 9 of the cap wafer 8 is removed from the separated portion 7 of the base wafer 6.

1-8. (canceled)

9. A method for producing semiconductor components having microstructures, the method comprising the following steps:
providing a base wafer having a plurality of microstructures;
arranging a cap wafer on the base wafer and integrally bonding the cap wafer to the base wafer to form a wafer assembly;
closing off the microstructures, at least on one side, with respect to an environment by the arranged cap wafer;
performing at least one manufacturing step and/or processing step and/or separating step; and
removing at least a part of the cap wafer or some separated portions of the cap wafer from the base wafer or from separated portions of the base wafer.

10. The method according to claim 9, wherein the cap wafer is bonded to the base wafer by anodic bonding, or by seal glass bonding, or by eutectic bonding.

11. The method according to claim 9, wherein at least a part of the cap wafer is detached from the base wafer by horizontal stealth dicing of a bond layer or the cap wafer.

12. The method according to claim 9, wherein at least some separated portions of the cap wafer are detached from separated portions of the base wafer by horizontal stealth dicing of a bond layer or of separated portions of the cap wafer.

13. The method according to claim 9, wherein a cap wafer structured in a direction of the base wafer is arranged on the base wafer and connected to the base wafer.

14. The method according to claim 9, wherein the microstructures are exposed by at least partially removing the cap wafer after the at least one manufacturing step and/or processing step and/or separating step.

15. The method according to claim 9, wherein, for at least partial removal of the cap wafer or portions of the cap wafer, at least one horizontally running stealth layer is introduced into the cap wafer or the portions of the cap wafer, and a detachment is carried out along a horizontally running stealth layer.

16. The method according to claim 9, wherein:
a plurality of semiconductor components with exposed microstructures are produced by at least partially detaching separated portions of the cap wafer; or
a plurality of semiconductor components with exposed microstructures are produced by at least partial detachment of the cap wafer and then separation.
